(19) United States
(12) Patent Application Publication
(10) Pub. No.: US 2010/0209720 A1
(43) Pub. Date: Aug. 19, 2010

(54) COATINGS

(75) Inventor: Bryan Greener, Heslington (GB)

Correspondence Address: Diana Houston;Smith & Nephew, Inc., 1450 Brooks Road, Memphis, TN, 38116, US

(73) Assignee: Smith & Nephew PLC, London (GB)

(21) Appl. No.: 12/669,271

(22) PCT Filed: Jun. 27, 2008
(86) PCT No.: PCT/GB2008/050514

§ 371 Date: Jan. 15, 2010

(30) Foreign Application Priority Data
Jul. 17, 2007 (GB) 0713802.7

(51) Int. Cl. B32B 15/04; B05D 3/00; C23C 16/06; C23C 16/08; C23C 16/513; B05D 3/06; B05D 3/10

(52) U.S. Cl. 428/457; 427/331; 427/250; 427/576; 427/352; 427/553; 427/343

(57) ABSTRACT

A process for the presentation of a uniform coating of a metal cluster species on a substrate is described, the process comprises the steps of: depositing an amorphous primer coating on the substrate; providing a source of metal ions for binding to the amorphous coating; and, generating metal clusters on the primer coating by applying reducing conditions thereto.

The present invention relates to a method for the presentation of coatings of metal cluster species upon the surface of or throughout a substrate material. In particular, though not exclusively, the present invention relates to a method of deposition of a primer on a substrate prior to the deposition of a subsequent metal layer.

The precise spatial distribution of metal atoms and ions occurs naturally in crystalline solids, including metals and ionic salts. The reproducible nature of these crystalline arrays has contributed to the commercial success of technologies relying on these properties, for example pharmaceutical formulations, silver halide photographic emulsions, semiconductors and LEDs. The preparation of simple ionic salts of controlled crystal morphology is well documented. Such compounds can be prepared using gas, liquid or plasma-phase deposition processes. In these cases, the aim is to produce a well-defined monolith of a discrete compound, for example a silicon dioxide crystal, or a well-defined batch of discrete crystals, for example aspirin. In these examples, the preparative environment is arranged to bias against imperfections in crystal growth or size distribution. In contrast to the growth of discrete nano-, micro- or macro-scopic crystals of metals or metal compounds, the deposition of uniform layers or these species upon the surface of a substrate is less easily achieved, especially on heterogeneous substrates not specifically prepared for surface deposition.

When metals or ionic compound are deposited from the gas, liquid or plasma phase onto the surface of a material, the individual atoms or ions are in a dissociated state prior to attachment to the substrate. When the first atoms or ions become attached to the surface they act as nucleation sites for further attachment. Thus, growth of crystallites tends to occur across the surface, creating a uniform but discontinuous coating of metal or ionic compound. Heterogeneity in the surface coating can lead to unacceptably variable physico-chemical performance, for example in catalysis, or unacceptable visual appearance, for example in anodised metals. Whilst it is recognised that surfaces prepared by the manipulation of matter at the atomic scale can overcome these shortcomings, these methods are not commercially feasible for the majority of applications.

However, the deposition of metal clusters on or throughout commercially available substrates is not easy to achieve in a sufficiently uniform manner to be visually acceptable.

It is an object of the present invention to provide a process for the presentation of uniform coatings of metal cluster species on the surface of or within substrates.

According to a first aspect of the present invention a process for the formation of a uniform coating of a metal cluster species on a substrate comprises the steps of: depositing an amorphous primer coating on the substrate; providing a source of metal ions for binding to the amorphous coating; and, generating metal clusters on the primer coating by applying reducing conditions thereto.

“Metal cluster species” are herein defined as arrangements of two or more metal atoms or ions within binding distance of one another. Typically, metal cluster species, as defined, appear coloured to normal human vision. Although no definite cut-off can be applied to define where metal clusters end and bulk metal begins, it is defined that metal clusters are limited to arrangements of 100000 or fewer metal atoms or ions, and more preferably arrangements of 10000or fewer metal atoms or ions.

“Uniform” is here defined as a coating not differing in observable colour to the human eye over the scale of the substrate device.

For the avoidance of doubt the coating of metal cluster species “on” a substrate includes a coating on the surface a dense, non-porous substrate and also the impregnation of a porous substrate.

The process according to the present invention for producing uniform coatings of metal cluster species on a substrate thus comprises three main steps:
(1) The coating or impregnation of the substrate with an amorphous material with an affinity for the binding of metal ions.
(2) The binding of metal ions to the primed substrate.
(3) The formation of metal clusters by treatment of the metal-ion coated or impregnated substrate with reducing conditions.

The process according to the present invention for the presentation of uniform coatings of metal cluster species on the surface of or within substrates has as a first step the deposition of an amorphous primer species prior to the deposition of metal ions and generation of metal clusters. The amorphous primer should not generate nucleated growth on the substrate, as is the case for crystalline or semi-crystalline solids, as outlined above as this can produce visual discontinuities observable to the human eye. The amorphous primer may preferably be an organic species, soluble in common solvents, to enable simple substrate coating by gas, plasma or liquid phase transfer. The primer may also be a species that is capable of ionic or electrostatic binding of metal ions, and therefore preferably contains nitrogen, sulphur or oxygen moieties or a combination of two or more of those.

In the first step of the process the substrate is coated with an amorphous material that does not result in significant growth of crystallites on the substrate. The purpose of this step is to provide a coating of uniform surface density that is difficult to achieve by depositing a crystalline material. Deposition of the amorphous material may be achieved by any means known to one skilled in the art such as from the gas, liquid or plasma phase, for example. The amorphous coating is most conveniently applied from a liquid phase, such as from a solution of the material in an aqueous or alcoholic solvent, for example. The amorphous material is suitably also a material capable of the binding of metal ions and is therefore a material containing nucleophilic moieties such as nitrogen, sulphur or oxygen atoms as stated above. More preferably, the amorphous material contains ligands with a high affinity for metal binding. Considering the requirement for an amorphous material, the material is conveniently an amorphous polymeric species. The amorphous material is preferably soluble in common solvents but substantially insoluble in aqueous media following coating of the substrate.

Suitable amorphous materials that meet the specified property requirements include both synthetic and natural polymeric anions that include but are not limited to: chitosan, keratin and poly(hexamethylenebiguanide). Substrate loadings of amorphous material are preferably below 10% w/w, more preferably below 1% w/w and more preferably still below 0.1% w/w. Too much primer is wasteful and if there is too little then a complete coverage of the substrate may not be achieved. The lower limit of primer loading is dependent upon the surface area of the substrate which, for a porous material, may vary greatly thus, it is not possible to set a lower limit in terms of % w/w.

In the case of using chitosan as the amorphous primer material, the coated substrate may be immersed in a neutral pH buffered solution to fix the primer to the substrate.

The primer is deposited on the substrate and the substrate is subsequently cleaned to remove excess primer, for example by washing. The primed substrate is then loaded or coated with metal ions by a suitable technique, for example, gas, liquid or plasma phase deposition. Deposition of the metal ions from the liquid phase from a solution containing the metal ions is preferred. The metal ions are bound to the primer in a discrete manner consistent with the uniform coating of the primer. Little or no nucleation occurs in this step of the process. The metal-loaded, primer-coated substrate is cleaned to remove excess metal ions, for example by washing. The metal-loaded, primer-coated substrate is then exposed to a reducing agent that is capable of reducing the oxidation state of the metal ions by at least one increment. The uniform distribution of primer-supported metal ions cluster in a rapid but controlled manner on the surface of the primer coating, generating an optically uniform coating of metal clusters on the substrate.

In the second step of the process, metal ions are bound to the coated substrate. The purpose of this step is the binding of metal ions to the amorphous liganding species coated on to the substrate in the absence of significant nucleation of particles on the substrate surface. “Particles in this sense mean agglomerations of ions or atoms which may be visible by light-based microscopic or direct observation as distinct from “clusters” which, as defined hereinabove, generally comprise less than 1000 atoms in size and which may be observed indirectly by electron microscopic techniques. The amorphous coating enables the deposition of discrete metal ions at a uniform density on or within the substrate, if porous. The metal ions may be deposited by any means known to one skilled in the art, for example from the gas, liquid or plasma phase as stated hereinabove. The metal ions are conveniently applied in the liquid phase by prior dissolution of a metal salt. The substrate may preferably be immersed in the solution of metal ions to facilitate metal ion loading. Excess metal ions may be rinsed from the substrate by immersion in a metal salt-free solvent. Suitable solvents for the second step of the process should not result in significant dissolution of the amorphous coating deposited in the first step of the process. Preferably, the solvent may be water. Metal salt concentrations can be formulated to achieve a specific metal ion loading density on the substrate. Suitable metal salts may include those sparingly and significantly soluble in common solvents. Preferably the metal salts may be soluble in aqueous or alcoholic solutions. Thus, suitable metal salts include, but are not restricted to, transition metal tetrafluoroborates and perchlorates, more preferably nitrates. The metal salt may preferably be one with a weakly coordinating counterion, so as not to significantly compete for the metal ions with the amorphous coating. Preferred counterions include, but are not restricted to tetrafluoroborate and perchlorate, more preferably nitrate counterions. Suitable metal ions can be any known including, silver, copper, gold, zinc, tungsten and bismuth.

Without wishing to be bound by any particular theory it is believed that the degree of metal ion loading it on the primer coated substrate can be from very low levels to 100%. A degree of overloading may be tolerated to the extent that the visual appearance of the resulting article or device is not impaired. Similarly, a degree of underloading may be tolerated or may be acceptable subject to the proviso that there are sufficient ions present on the substrate to generate clusters in the succeeding reduction step.

In the third step of the process, the metal ions bound to the amorphous coating attached to the substrate may be made to form metal clusters by exposure to reducing conditions. “Reducing conditions” as used herein is taken to mean any environment in which electrons can be donated to the bound metal ions by, for example, exposure to light or the application of a reducing agent. Where a reducing agent is applied, this may preferably be achieved by immersion of the substrate in a solution of the reducing agent. Suitable reducing agents include, but are not restricted to: sodium borohydride, oxalic acid, diisobutylaluminium hydride, lithium aluminium hydride, potassium ferricyanide and hydrazine, for example. Preferably, the reducing agent may be light or a solution of sodium borohydride . It is possible that both forms of reducing agent may be used simultaneously or sequentially. Sufficient exposure to the reducing environment is arranged to bring about the desired concentration and size of metal clusters. Sufficient exposure can be achieved by controlling exposure time and/or reductant concentration (in solution) or intensity (light).

The size and spacing of the metal clusters can be thus controlled by applying suitable concentrations of primer, metal ions and reducing agent.

Between each step of the process, excess reagents may be washed from the substrate to avoid co-deposition of two or more of the reagents being applied; this can lead to deleterious discolouration due to nucleolytic deposition. Suitable washing solvents include those used to apply each reagent.

According to a second aspect of the present invention there are provided articles when made by the process of the first aspect of the present invention.

Suitable substrates for the presentation of metal clusters by the method disclosed include those made of natural and synthetic materials, in particular polymeric materials. Examples of such materials include, but are not restricted to: cotton, cellulose, starch, collagen, gelatin, polyethylene, polypropylene, polyisobutylene, polystyrene, polyvinylchloride, polyurethane, polyethyleneterephthalate, polytetrafluoroethylene and silicone-based polymers. This list of commonly occurring natural and synthetic polymers demonstrate a lack of strong metal ion liganding groups in their structures. Thus, these materials are good candidates as substrates for the process according to the first aspect of the present invention.

The substrate may be in any material form, including: a solid or semi-solid monolith of any geometry; a material comprised of fibres or filaments, for example a non-woven material or a woven material; a foam of any geometry. The substrate may display any physical properties provided that a nanoscopically stable surface can be presented during the coating process. Preferably the substrate material is a gel, an elastomer or an amorphous or crystalline solid.

For medical applications, the substrate is preferably one commonly applied in the medical arena such as stainless steel, cotton gauze, polyethylene and polyurethane and silicone-based polymers, for example.

The substrate can be presented, by means known to one skilled in the art, to a series of environments that allow each of the treatment and washing steps to be achieved in an economical manner.

According to a third aspect of the present invention there is provided a medical application of the process and articles resulting from the first and second aspects of the present invention.

Suitable medical applications include the use of devices coated or impregnated with metal clusters, including implants, in-dwelling devices and topical devices. Implantable devices include natural and synthetic implants, including stents, breast implants, shunts, artificial hips, artificial knees, artificial bone prosthetics and bone fixation devices such as plates, screws and nails. In-dwelling devices include catheters, drains, IV lines, K-wires and feeding tubes. Topical devices include transdermal delivery patches, wound management devices and support garments. None of the lists of examples given above for the various types and categories of medical applications are exhaustive but merely illustrative of potential areas of application of the present invention.

In the specific case of wound management devices, this includes absorbent and non-absorbent polyurethane dressings, packing materials such as foam and gauze or any arrangements of these materials and substrates for the delivery of active agents including pharmaceuticals or human- or animal-derived species to the wound. Packing materials for a wound dressing for topical negative pressure therapy may be one example of a use of materials made by the present invention.

In order that the present invention may be more fully understood, examples will now be described by way of illustration only with reference to the accompanying drawings, of which:

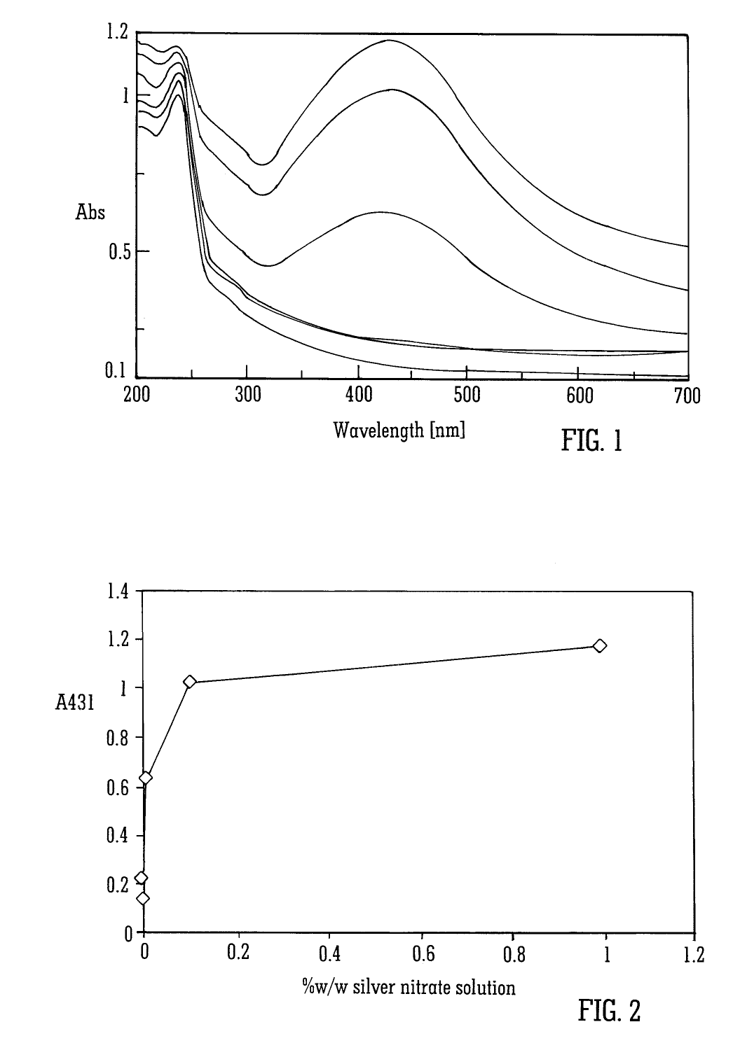

FIG. 1 shows a graph of the UV-vis absorption spectra of silver clusters generated on PHMB-impregnated gauze following immersion of the gauze in silver nitrate solutions of varying concentration [1.0% w.w (top), 0.1% w/w, 0.01% w/w, 0.001% w/w, 0.0001% w/w and 0% w/w (bottom)] and subsequent reduction with sodium borohydride solution, see Example 4; and

FIG. 2 which shows a graph of the increase in absorbance at 431 nm (the plasmon absorbance wavelength of silver clusters) with silver nitrate solution concentration during the preparations listed in Example 4.

### EXAMPLE 1

Impregnation of cotton gauze with a nitrogen-rich amorphous polymer (chitosan).

A roll of standard cotton gauze was immersed in a 0.1% w/w solution of chitosan dissolved in dilute acetic acid. The gauze roll was manipulated to wet out fully and withdrawn from the solution. Excess liquid was expelled from the roll with gentle squeezing. The wet roll was immersed in a neutral pH buffered solution to fix the chitosan to the gauze. The gauze was squeezed several times in the neutral pH solution and removed. Excess solution was expelled from the roll and the roll was dried at 40° C. overnight.

Loading of chitosan-impregnated cotton gauze with gold ions.

The gauze prepared as above was immersed in a 0.01% w/w aqueous solution of gold(III) chloride. The gauze rapidly took on the colour of the yellow gold(III) ions and the solution discoloured. The gauze was removed from the solution and rinsed repeatedly in distilled water, with squeezing. The gauze was dried at 40° C. overnight.

Generation of gold clusters on cotton gauze.

The gold(III) ion-loaded, chitosan impregnated gauze produced as described above was immersed in a 0.01% w/w aqueous solution of sodium borohydride for 60 seconds, with squeezing. The gauze roll rapidly changed colour from yellow to pink, indicating the formation of gold clusters. The gauze roll was repeatedly washed immediately in distilled water, with squeezing. The gauze was dried at 40° C. overnight.

### EXAMPLE 2

Loading of polyhexamethylenebiguanide (PHMB) impregnated gauze with silver ions.

A commercially available PHMB-impregnated gauze (Kerlix AMD, Kendall—Trade name) was immersed in a 0.1% w/w aqueous solution of silver nitrate for 15 minutes. The gauze was removed from the solution and rinsed repeatedly in distilled water, with squeezing. The gauze was dried at 40° C. overnight.

Generation of silver clusters on cotton gauze.

The silver ion-loaded, PHMB-impregnated gauze produced described above was immersed in a 0.01% w/w aqueous solution of sodium borohydride for 120 seconds, with squeezing. The gauze roll rapidly changed colour from white to tan, indicating the formation of silver clusters. The gauze roll was repeatedly washed immediately in distilled water, with squeezing. The gauze was dried at 40° C. overnight.

### EXAMPLE 3(NOT ACCORDING TO THE PRESENT INVENTION)

Attempted generation of silver clusters on cotton gauze in the absence of amorphous primer coat.

The procedure undertaken in Example 2 was repeated on standard gauze. The end product varied in colour, from grey to pink to tan. The colour uniformity was extremely poor and single-colour patches extended several centimetres.

### EXAMPLE 4

Variation of silver cluster loading density on polyhexamethylenebiguanide (PHMB) impregnated gauze.

The procedure undertaken in Example 2 above was repeated with varying concentrations of silver nitrate solution: 1.0% w.w, 0.1% w/w, 0.01% w/w, 0.001% w/w, 0.0001% w/w and 0% w/w. Each sample was individually treated as in Example 5. The resulting series of material varied in colour from white (0% w/w treatment) to tan (0.1% w/w treatment) to grey-tan (1.0% w/w treatment).

Each sample had its diffuse reflectance UV-vis absorbance recorded. The silver cluster absorption occurred at 431 nm. The variation in this absorbance with concentration of silver nitrate loading solution was plotted and the results shown in FIGS. 1 and 2.

FIG. 1 shows UV-vis absorbance spectra of silver-cluster loaded gauze (FIG.1) with 1.0% w/w (top) running down to 0% w/w (bottom) and, trend in A431 with silver nitrate loading solution concentration (FIG. 2). FIG. 1 shows that increasing the concentration of the metal-loading bath leads to a subsequent increase in the cluster density on the device; the intensity of the absorbance at 431 nm varies in a linear manner with cluster concentration (Beer-Lambert Law). When A431 is plotted against metal-loading bath concentration, a cluster saturation level can be observed (FIG. 2). From this, it can be seen that, for this example, there is little value in going beyond a bath concentration of 0.2% w/w silver nitrate as significant increases in cluster density are not achieved beyond this point.

It was observed, in this set of results using varying silver nitrate concentrations in Example 4, that negligible silver cluster formation took place at silver nitrate concentrations at or below 0.001% w/w. Above this concentration, significant cluster formation occurred and the coatings were visibly uniform at 0.01% w/w and 0.1% w/w loading solution. Above these concentrations, at 1.0% w/w, over-deposition occurred and this resulted in visible coating non-uniformity.

Throughout the description and claims of this specification, the words “comprise” and “contain” and variations of the words, for example “comprising” and “comprises”, means “including but not limited to”, and is not intended to (and does not) exclude other moieties, additives, components, integers or steps.

Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith.

1. A process for the presentation of a uniform coating of a metal cluster species on a substrate comprising: depositing an amorphous material on the substrate to form an amorphous primer coating on the substrate; providing a source of metal ions for binding to the amorphous primer coating to generate a metal ion coated substrate; and generating metal clusters on the substrate by applying reducing conditions to the metal ion coated substrate.

2. The process according to claim 1 wherein the amorphous material is an organic species.

3. The process according to either claim 1 wherein the amorphous material is deposited by a technique selected from: gas, plasma or liquid phase transfer.

4. The process according to claim 1 wherein the amorphous material contains at least one of: nitrogen, sulphur or oxygen moieties.

5. The process according to claim 3 wherein the amorphous material is deposited from a solution of the amorphous material in one of: an aqueous or an alcoholic solvent.

6. The process according to claim 1 wherein the amorphous material has ligands with a high affinity for metal binding.

7. The process according claim 1 wherein the amorphous material is substantially insoluble in aqueous media following coating of the substrate.

8. The process according to claim 1 wherein the amorphous material is chosen from the group comprising: chitosan, keratin and poly(hexamethylenebiguanide).

9. The process according to claim 1 wherein substrate loading of the amorphous material lies in the range from less than 10% w/w to 0.1% w/w and below.

10. The process according to claim 1 comprising washing the amorphous primer coated substrate after deposition of the amorphous material.

11. The process according to claim 1 wherein providing a source of metal ions comprises coating the amorphous primer coating with metal ions by a technique chosen from: gas, liquid and plasma phase deposition.

12. The process according to claim 1 wherein the source of metal ions includes a solution of a metal salt containing the metal ions.

13. The process according to claim 1 wherein the metal ions are sourced from the group of materials comprising: transition metal tetrafluoroborates, transition metal perchlorates and transition metal nitrates.

14. The process according to claim 1 wherein the metal ions are selected from the group comprising: silver, copper, gold, zinc, tungsten and bismuth.

15. The process according to claim 1 comprising washing the metal ion coated substrate.

16. The process according claim 1 wherein the metal ion coated substrate is subjected to a reducing step which reduces the oxidation state of the metal ions by at least one increment.

17. The process according to claim 1 wherein the reducing conditions include exposure to light or application of a reducing agent.

18. The process according to claim 17 wherein a reducing agent is selected from the group comprising: sodium borohydride, oxalic acid, diisobutylaluminium hydride, lithium aluminium hydride, potassium ferricyanide or hydrazine.

19. The process according to claim 1 wherein the substrate is selected from the group comprising: cotton, cellulose, starch, collagen, gelatin, polyethylene, polypropylene, polyisobutylene, polystyrene, polyvinylchloride, polyurethane, polyethyleneterephthalate, polytetrafluoroethylene or silicone-based polymers.

20. The process according to claim 1 wherein the substrate is one of: a gel, an elastomer, an amorphous solid or a crystalline solid.

21. An article having a metal coating produced by the process of claim 1.

22. (canceled)

23. (canceled)

24. (canceled)

25. (canceled)
